(19) United States
(12) Patent Application Publication
(10) Pub. No.: US 2011/0117747 A1
(43) Pub. Date: May 19, 2011

(54) METHOD OF FABRICATING SINGLE CHIP FOR INTEGRATING FIELD-EFFECT TRANSISTOR INTO MEMS STRUCTURE

(75) Inventors: Chin-Long Wey, Hsinchu (TW); Chin-Fong Chiu, Hsinchu (TW); Ying-Zong Juang, Hsinchu (TW); Hann-Huei Tsai, Hsinchu (TW); Sheng-Hsiang Tseng, Hsinchu (TW); Hsin-Hao Liao, Hsinchu (TW)

(73) Assignee: National Chip Implementation Center National Applied Research Laboratories, Hsinchu City (TW)

(21) Appl. No.: 12/652,068

(22) Filed: Jan. 5, 2010

(30) Foreign Application Priority Data
Nov. 18, 2009 (TW) 098139061

(51) Int. Cl. H01L 21/3065

(52) U.S. Cl. 438/710; 257/E21.218

(57) ABSTRACT

A method of fabricating a single chip for integrating a field-effect transistor into a microelectromechanical systems (MEMS) structure is provided. The method includes the steps of: providing a substrate having thereon at least one transistor structure, a MEMS structure and a blocking structure, wherein the blocking structure encircles the MEMS structure to separate the MEMS structure from the transistor structure; forming a masking layer for covering the transistor structure, the MEMS structure and the blocking structure; forming a patterned photoresist layer on the masking layer; performing a first etching process by using the patterned photoresist layer to remove the masking layer on the MEMS structure; and performing a second etching process by removing a portion of the MEMS structure to form a plurality of microstructures such that a relative motion among the microstructures takes place in a direction perpendicular to the substrate.

### BACKGROUND OF THE INVENTION

1. Technical Field

The present invention relates to a method of fabricating a single chip for integrating a field-effect transistor into a microelectromechanical systems (MEMS) structure. More particularly, the present invention relates to a fabrication method compatible with a transistor fabrication process and configured to fabricate a single chip for integrating a field-effect transistor into a MEMS structure with an out-of-plane sensing structure.

2. Description of Related Art

In general, a conventional method of fabricating a single chip for integrating a complementary metal-oxide-semiconductor (CMOS) into a microelectromechanical systems (MEMS) sensor involves removing, after a standard CMOS fabrication process, a dielectric oxide layer by etching, and forming a sensor structure layer from a polysilicon layer and a metal layer previously defined by the standard CMOS fabrication process.

FIG. 1A and FIG. 1B show schematic views of a conventional method of fabricating a single chip by dry plasma etching so as to integrate a CMOS circuit into a MEMS sensor. FIG. 2A and FIG. 2B show schematic views of a conventional method of fabricating a single chip by wet bench etching so as to integrate a CMOS circuit into a MEMS sensor.

Shown in FIG. 1A and FIG. 1B are two methods disclosed by prior art. One method uses the uppermost layer (metal layer 11) in a CMOS circuit as an etch mask (shown in FIG. 1A), which undergoes dry plasma etching This etch mask also serves as a passivation layer that thereby defines the sensor. Another method (U.S. Pat. No. 7,435,612 B2) discloses a mask 12, which is provided on an optional basis to define the sensor. In this method, silicon dioxide, which is layered between a CMOS circuit and a MEMS structure, will be etched by a dry plasma etching process performed vertically and anisotropically. An isotropic etching process is then performed on a substrate 10 so as to release a suspended MEMS structure. However, this method is only useful for fabricating horizontal in-plane sensors and cannot be utilized for vertical out-of-plane capacitive sensors.

Referring to FIG. 2A and FIG. 2B, the prior art discloses a method that employs wet bench etching, uses a metal layer 13 as a sensor sacrificial layer, and uses silicon dioxide between the CMOS circuit and the MEMS structure as a structure layer. The method is useful for fabricating a CMOS circuit and a suspended out-of-plane MEMS sensing structure. However, as shown in FIG. 2B which is a partial enlarged view of FIG. 2A, wet bench etching has to be followed by two steps, namely rinsing and drying. These steps are necessary because a trace of acidic solution held in a bend is unlikely to dry and thus contributes to stiction between the structure and the substrate 10, and as a consequence the MEMS structure is rendered unworkable.

U.S. Pat. No. 6,238,580 discloses a method that employs hydrofluoric acid vapor-phase etching (HF VPE), uses silicon dioxide as a sacrificial layer and polysilicon as a structure layer so as to efficiently fabricate an out-of-plane sensing structure without causing stiction, and the method is applicable to a MEMS platform. The method entails performing a high-temperature polysilicon layer deposition process at a later stage, but it is impossible for a CMOS fabrication process to be followed by the high-temperature polysilicon layer deposition process. Hence, the method disclosed in U.S. Pat. No. 6,238,580 is inapplicable to a platform for integrating a CMOS circuit into a MEMS sensor.

### BRIEF SUMMARY OF THE INVENTION

The present invention provides a method of fabricating a single chip for integrating a field-effect transistor into a microelectromechanical systems (MEMS) structure such that the single chip thus fabricated is effective in integrating a complementary metal-oxide-semiconductor (CMOS) circuit into an out-of-plane MEMS sensor, wherein a masking layer formed by chemical vapor deposition (CVD) functions as an etch-stop layer in hydrofluoric acid vapor-phase etching (HF VPE), so as to efficiently fabricate horizontal and vertical out-of-plane sensing devices.

The present invention provides a method of fabricating a single chip for integrating a field-effect transistor into a MEMS structure such that the single chip fabricated by the method has a high capacitance sensitivity and a much smaller pitch than one typical of dry plasma etching Stiction found between the structure and a substrate as a result of wet bench etching does not occur to the method of the present invention. Most importantly, a masking layer deposited by the method of the present invention can be efficiently removed by an etching process at a later stage without imposing any electrical impact on a CMOS circuit component area.

The present invention provides a method of fabricating a single chip for integrating a field-effect transistor into a MEMS structure such that the method is fully compatible with a standard CMOS fabrication process to thereby enable batch production and effective reduction of costs.

To achieve the above and other objectives and functions, the present invention provides a method of fabricating a single chip for integrating a field-effect transistor into a MEMS structure, comprising the steps of: providing a substrate having thereon at least one transistor structure, a MEMS structure, and a blocking structure, the blocking structure encircling the MEMS structure to separate the MEMS structure from the transistor structure; forming a masking layer for covering the s transistor structure, the MEMS structure, and the blocking structure; forming a patterned photoresist layer on the masking layer; performing a first etching process by using the patterned photoresist layer to remove the masking layer on the MEMS structure; and performing a second etching process by removing a portion of the MEMS structure to form a plurality of microstructures such that a relative motion among the microstructures takes place in a direction perpendicular to the substrate.

Implementation of the present invention at least involves the following inventive steps:

1. Upon completion of a standard CMOS fabrication process, a chemical vapor deposition (CVD) process is carried out to deposit a masking layer on the surface of a single chip so as for the masking layer to function as an etch-stop layer in hydrofluoric acid vapor-phase etching (HF VPE), protect a CMOS circuit component area, and effectively mitigate the effect of additional thermal budget on the characteristics of CMOS circuit components, not to mention that the CVD process for depositing the mask layer is fully compatible with a standard CMOS fabrication process.

2. The method of the present invention adopts novel HF VPE technique. HF VPE is highly selective in its etching process. Hence, silicon dioxide in the MEMS structure is etched away by HF VPE to a greater extent than the metal and the masking layer. Owing to the masking layer on the transistor structure and the metal in the blocking structure, not only is the silicon dioxide in the MEMS component area efficiently removed, but the CMOS circuit component area remains unaffected by HF VPE. Thus, out-of-plane MEMS sensors that orientate in horizontal directions and vertical directions can be fabricated in the same fabrication process.

The features and advantages of the present invention are described in detail in the preferred embodiments of the present invention to enable persons skilled in the art to gain insight into the technical disclosure in the present invention and implement the present invention accordingly and readily understand the objectives and advantages of the present invention by making reference to the disclosure contained in the specification, the claims, and the drawings of the present invention.

### BRIEF DESCRIPTION OF THE SEVERAL VIEWS OF THE DRAWINGS

FIG. 1A and FIG. 1B are schematic views of a conventional method of fabricating a single chip by dry plasma etching so as to integrate a complementary metal-oxide-semiconductor (CMOS) circuit into a microelectromechanical systems (MEMS) sensor;

FIG. 2A and FIG. 2B are schematic views of a conventional method of fabricating a single chip by wet bench etching so as to integrate a CMOS circuit into a MEMS sensor;

FIG. 3 is a flow chart of a method of fabricating a single chip for integrating a field-effect transistor into a MEMS structure according to the present invention; and

FIG. 4 through FIG. 9 are schematic views of structure and configuration corresponding to individual steps illustrated in FIG. 3;

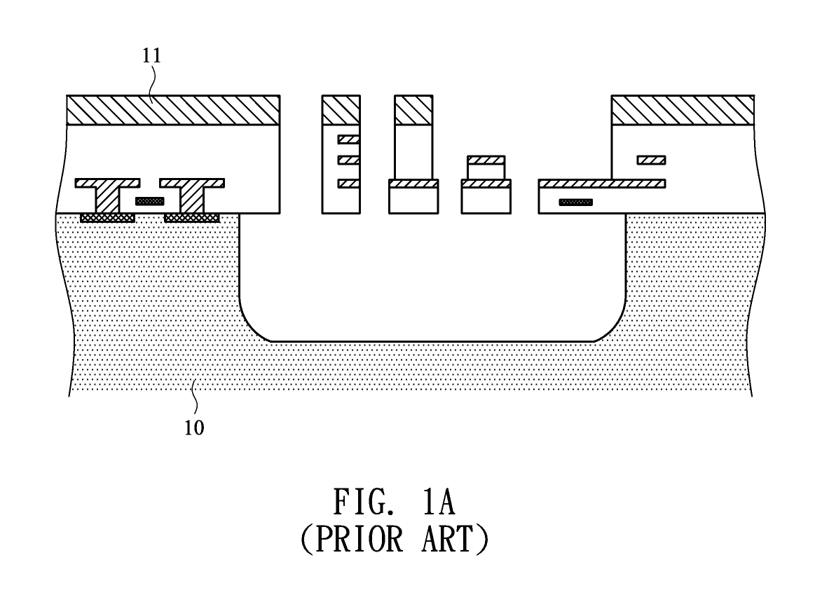

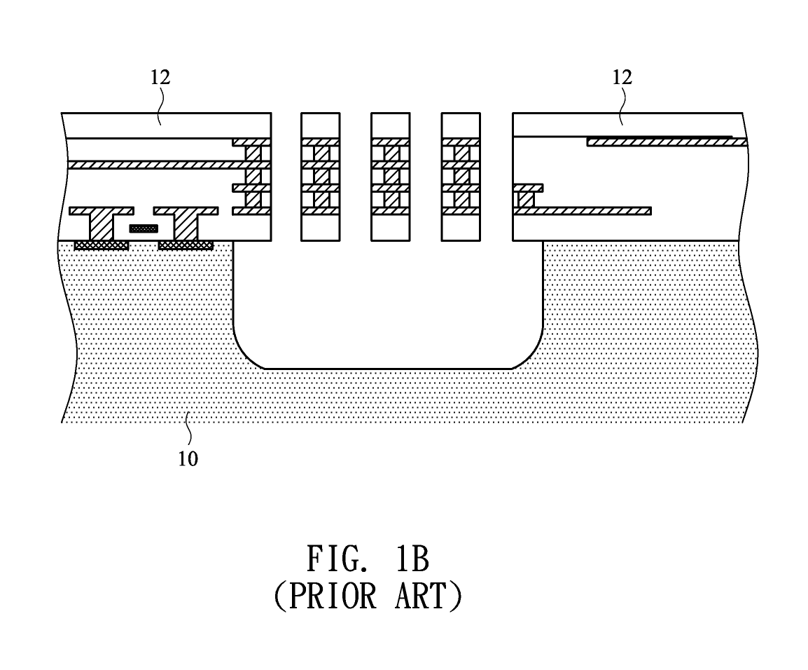

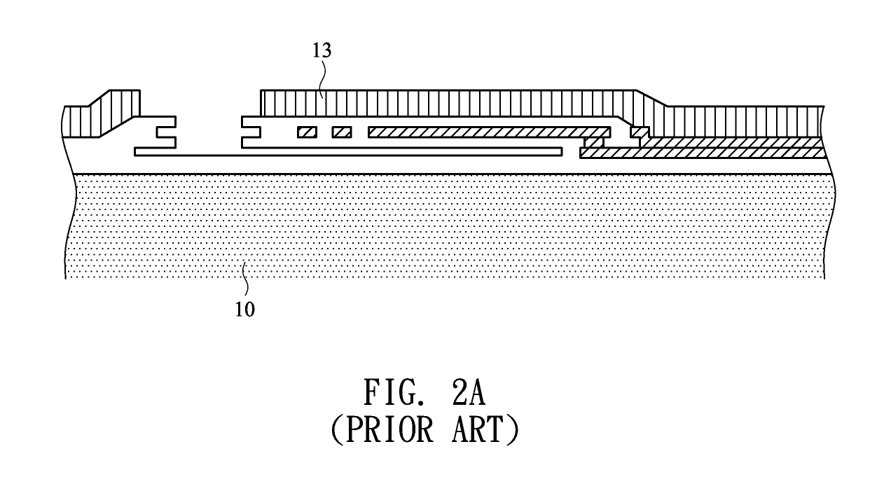

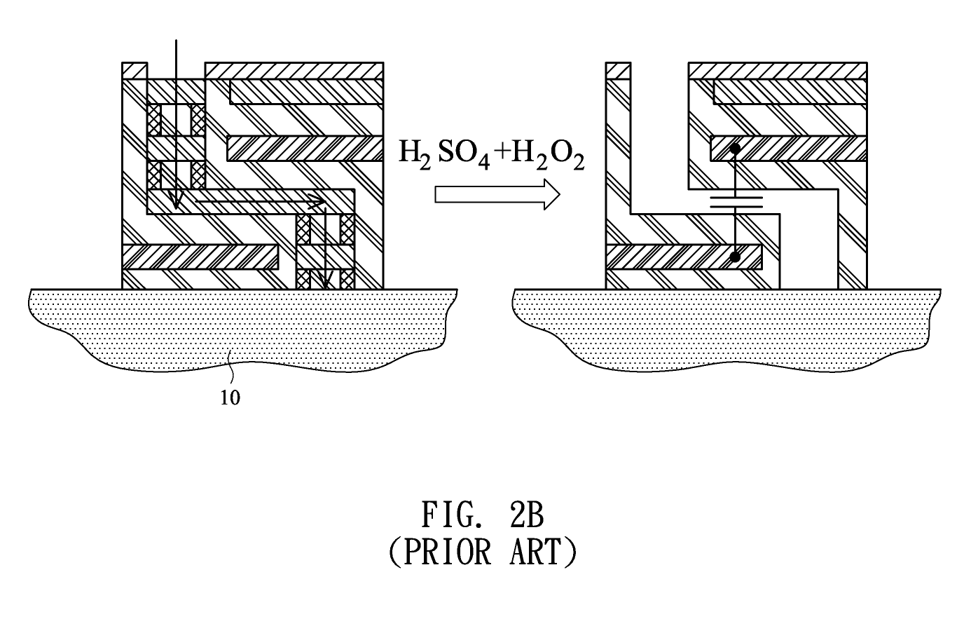

### DETAILED DESCRIPTION OF THE INVENTION

To provide a comprehensible description of the present invention, the method in the preferred embodiments of the present invention is illustrated with the structural features of a single chip for integrating a complementary metal-oxide-semiconductor (CMOS) into a microelectromechanical systems (MEMS) sensor. However, the method of the present invention is also applicable to any other similar integration-oriented structures and fabrication processes without departing from the spirit embodied in the present invention.

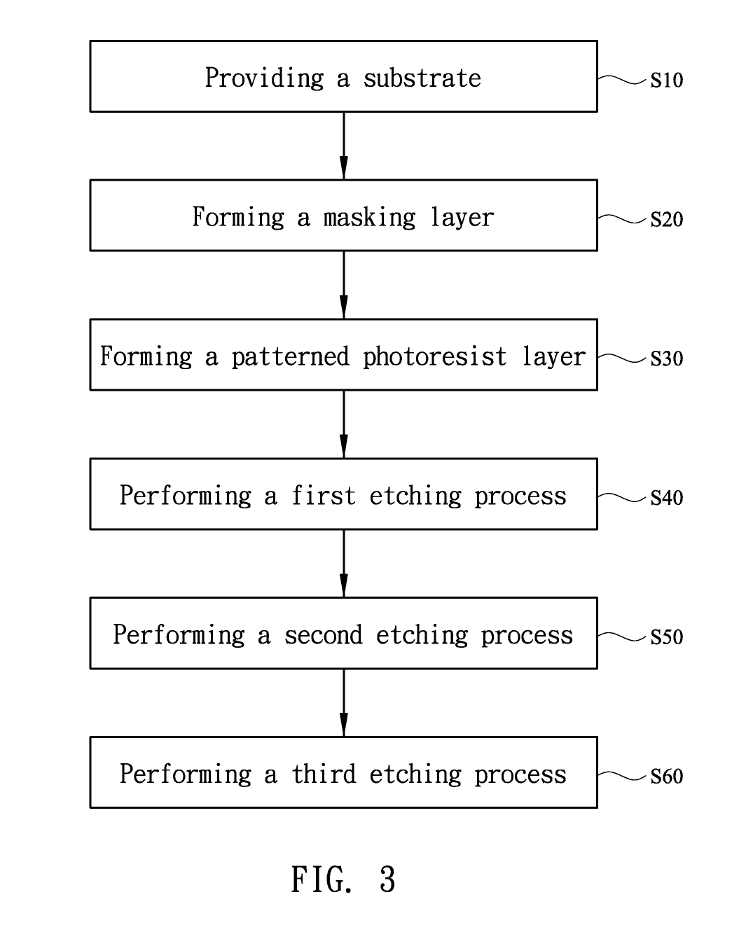

Referring to FIG. 3, there is shown a flow chart of a method of fabricating a single chip for integrating a field-effect transistor into a microelectromechanical systems (MEMS) structure according to one embodiment of the present invention. As shown in the drawing, the method includes the steps of: providing a substrate (step S10), forming a masking layer (step S20), forming a patterned photoresist layer (step S30), performing a first etching process (step S40), performing a second etching process (step S50), and performing a third etching process (step S60). The steps and the structure and configuration of the steps are described in sequence below.

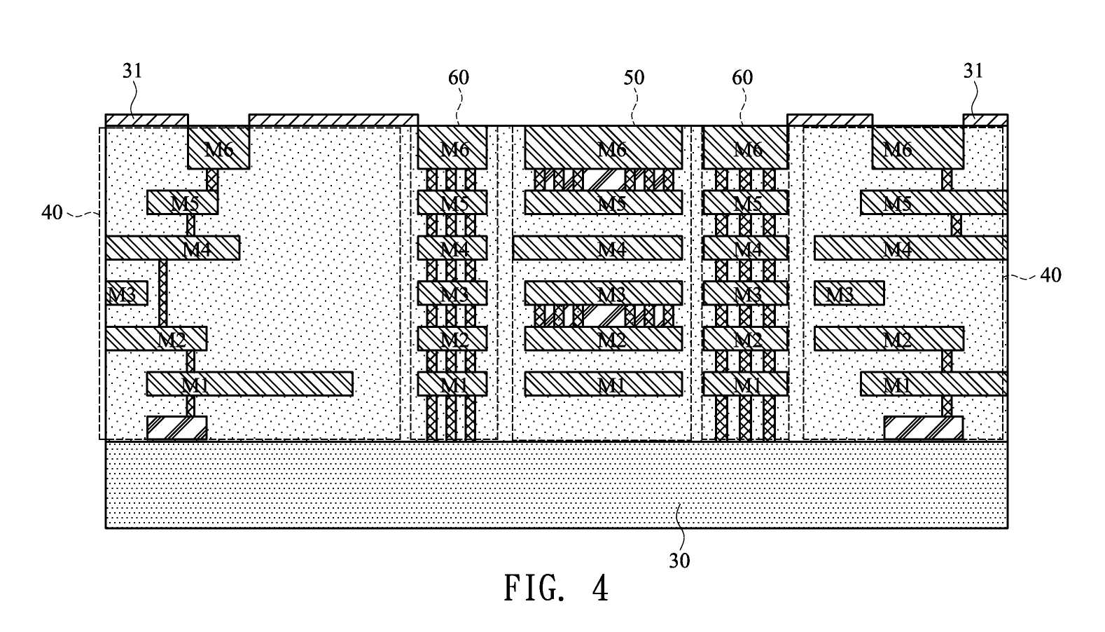

Referring to FIG. 4, there is shown a schematic view of the structure corresponding to step S10. In step S10, a standard CMOS fabrication process is performed on a substrate 30 so as to form at least one transistor structure 40, a MEMS structure 50, and a blocking structure 60 on the substrate 30, wherein the blocking structure 60 encircles the MEMS structure 50 to separate the MEMS structure 50 from the transistor structure 40. The transistor structure 40 is covered with a passivation layer 31, though allowing metal M6 in the transistor structure 40, the MEMS structure 50, and the blocking structure 60 to be exposed. In a preferred embodiment, the transistor structure 40 is a CMOS component, and the MEMS structure 50 is a MEMS sensor. The blocking structure 60 is made of metal and configured to stop an etching reaction medium from etching into the transistor structure 40 from the MEMS structure 50.

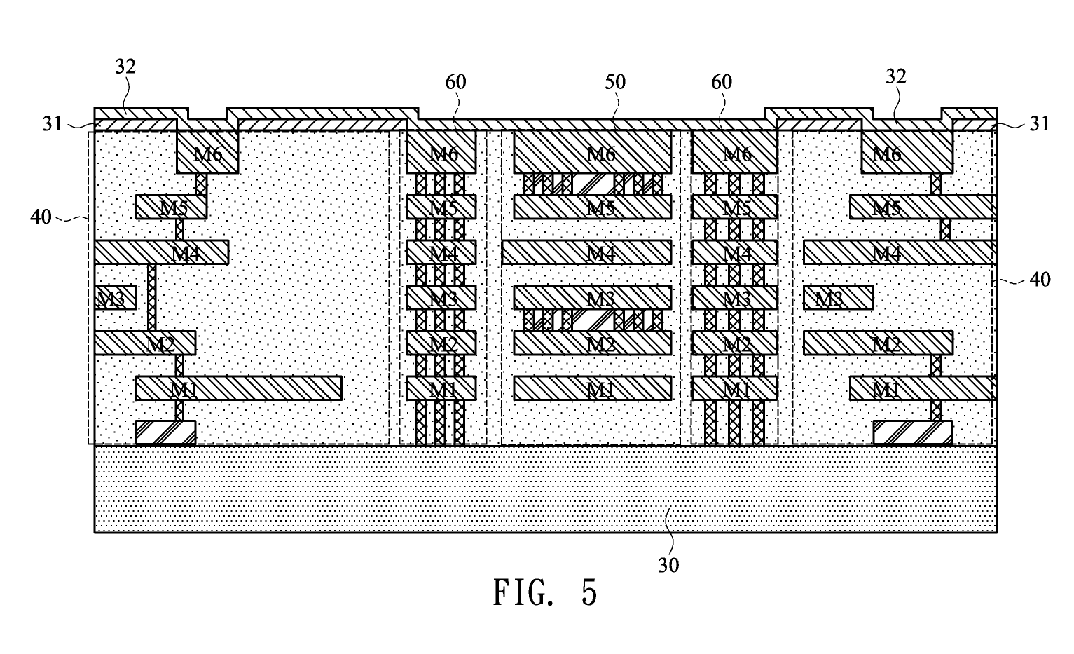

Referring to FIG. 5, there is shown a schematic view of the structure corresponding to step S20. In step S20, a chemical vapor deposition (CVD) process is carried out to form a masking layer 32 for covering the passivation layer 31 on the transistor structure 40, the MEMS structure 50, and the blocking structure 60. The masking layer 32 is made of monocrystalline silicon, polysilicon, amorphous silicon, or silicon-germanium.

In a preferred embodiment, the masking layer 32 is an amorphous silicon layer formed by a low-temperature chemical vapor deposition (CVD) process, and the amorphous silicon layer protects the transistor structure 40 by functioning as an etch-stop layer in a hydrofluoric acid vapor-phase etching (HF VPE) process afterward. The low-temperature CVD process not only effectively mitigates the effect of additional thermal budget on the characteristics of CMOS circuit components but also is fully compatible with a standard CMOS fabrication process.

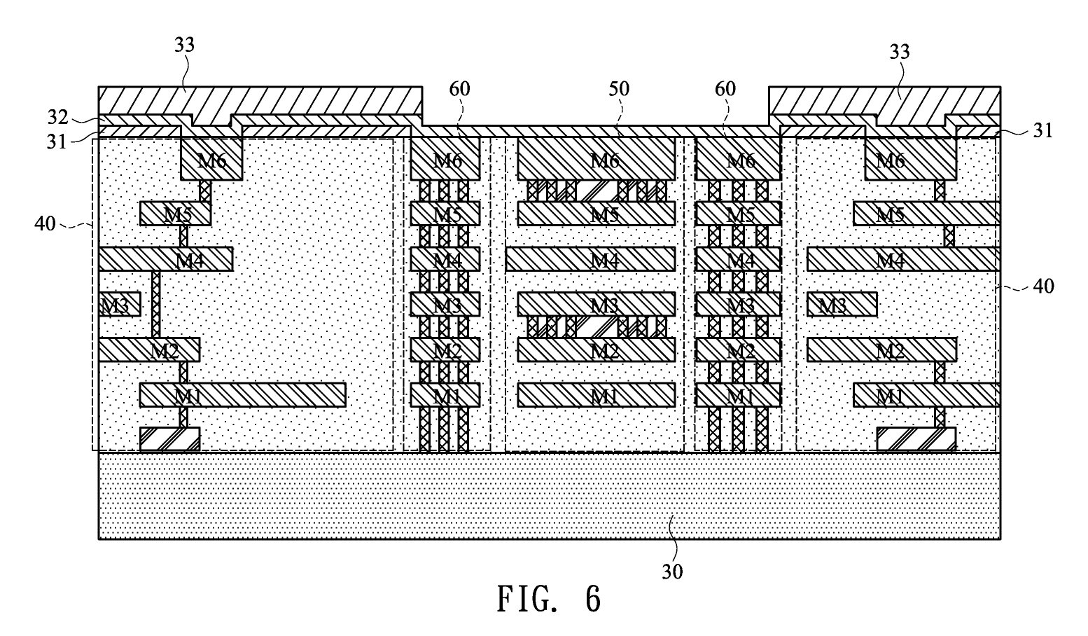

Referring to FIG. 6, there is shown a schematic view of the structure corresponding to step S30. In step S30, a patterned photoresist layer 33 is formed on the masking layer 32, and the patterned photoresist layer 33 thus formed is configured to define a release region of the MEMS structure 50.

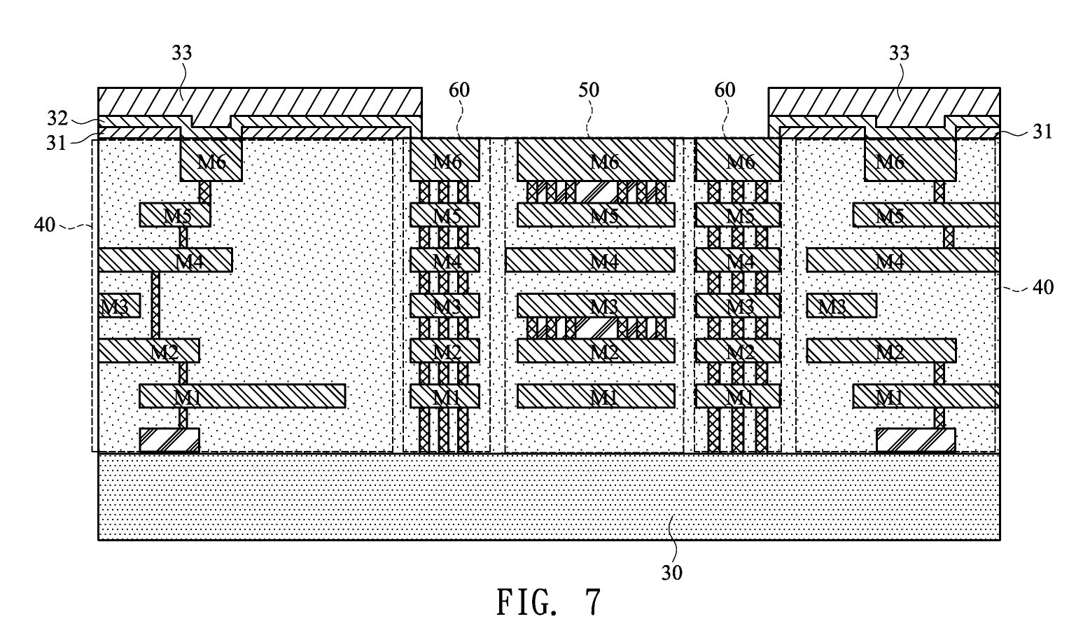

Referring to FIG. 7, there is shown a schematic view of the structure corresponding to step S40. In step S40, the masking layer 32 on the MEMS structure 50 is removed by means of the patterned photoresist layer 33 in the first etching process using anisotropic dry plasma etching. Thus, an etching window for a sensing area (MEMS component area) is formed.

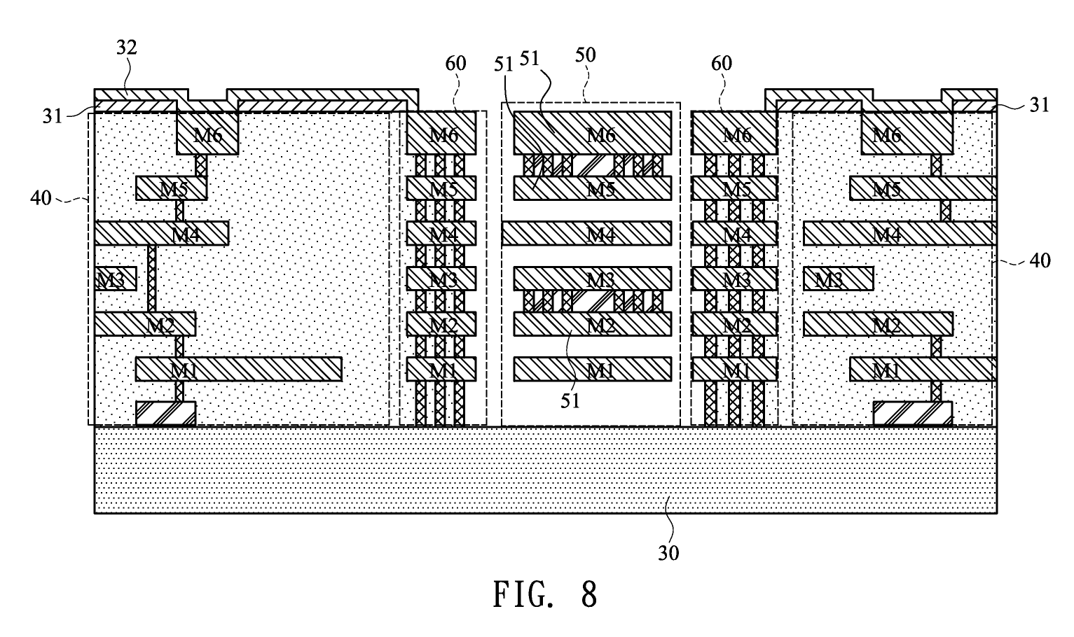

Referring to FIG. 8, there is shown a schematic view of the structure corresponding to step S50. In step S50, silicon dioxide which is present in the MEMS structure 50 but is not protected by metal is etched away by the second etching process using HF VPE to thereby form a plurality of microstructures 51. A relative motion among the microstructures 51 can take place in a direction perpendicular to the substrate 30, because the second etching process has completely removed the silicon dioxide otherwise present between the horizontally-aligned microstructures 51.

HF VPE is highly selective in its etching process. Hence, the silicon dioxide in the MEMS structure 50 is etched away by HF VPE to a greater extent than the metal (such as M1 through M6) and the masking layer 32. In other words, during the HF VPE process, the silicon dioxide in the MEMS structure 50 is etched away, but the suspended microstructures 51 in the MEMS structure 50 are completely released, resulting in out-of-plane MEMS sensors that orientate in horizontal directions and vertical directions. Also, the transistor structure 40 is protected by the masking layer 32 in the horizontal direction and protected by metals (such as M1 through M6) in the blocking structure 60 in the vertical direction, and thus the transistor structure 40 is fully protected against erosion by an etching reaction medium used in HF VPE.

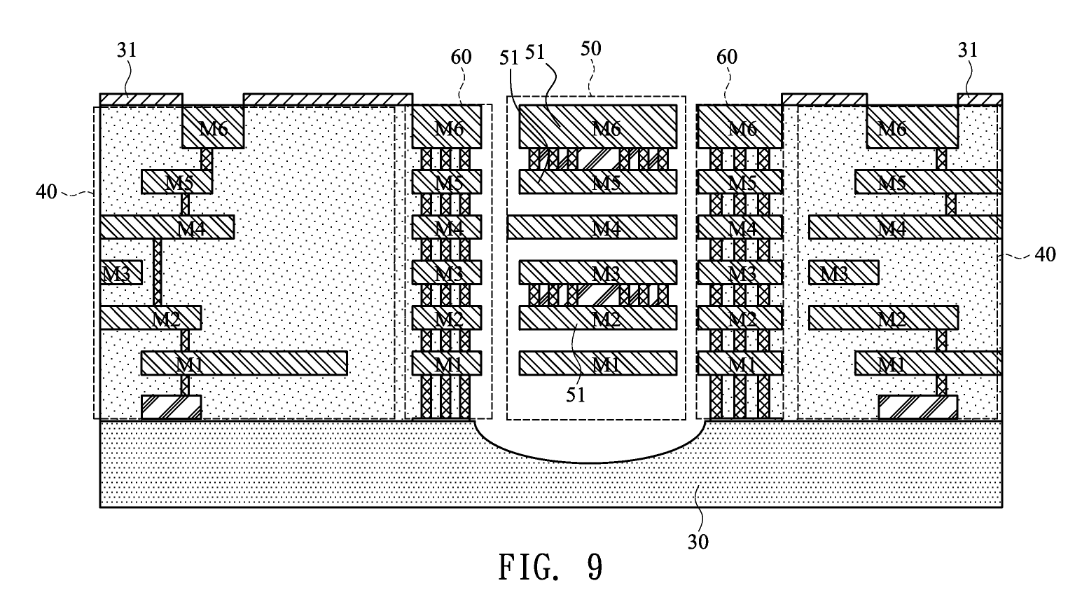

Referring to FIG. 9, there is shown a schematic view of the structure corresponding to step S60. Step S60 involves performing a third etching process by isotropic dry plasma etching to remove the masking layer 32 in whole and a portion of the substrate 30 beneath the MEMS structure 50. Hence, step S60 effectively expands the room for downward movement of the suspended microstructures 51, thereby increasing the range of operation of a sensor. Moreover, step S60 removes the masking layer 32 on the transistor structure 40 to mitigate any negative effect on the electrical characteristics of the transistor structure 40, so as to finalize the fabrication of a single chip for integrating a field-effect transistor into an out-of-plane MEMS sensor.

The foregoing embodiments are provided to illustrate and disclose the technical features of the present invention so as to enable persons skilled in the art to understand the disclosure of the present invention and implement the present invention accordingly, and are not intended to be restrictive of the scope of the present invention. Hence, all equivalent modifications and variations made to the foregoing embodiments without departing from the spirit and principles in the disclosure of the present invention should fall within the scope of the invention as set forth in the appended claims.

What is claimed is:

1. A method of fabricating a single chip for integrating a field-effect transistor into a microelectromechanical systems (MEMS) structure, comprising the steps of:
providing a substrate having thereon at least one transistor structure, a MEMS structure, and a blocking structure, the blocking structure encircling the MEMS structure to separate the MEMS structure from the said transistor structure;
forming a masking layer for covering the said transistor structure, the MEMS structure, and the blocking structure;
forming a patterned photoresist layer on the masking layer;
performing a first etching process by using the patterned photoresist layer to remove the masking layer on the MEMS structure; and
performing a second etching process by removing a portion of the MEMS structure to form a plurality of microstructures such that a relative motion among the microstructures takes place in a direction perpendicular to the substrate.

2. The method of claim 1, wherein the masking layer is made of monocrystalline silicon, polysilicon, amorphous silicon, or silicon-germanium.

3. The method of claim 1, wherein the masking layer is an amorphous silicon layer formed by low-temperature chemical vapor deposition (CVD).

4. The method of claim 1, wherein the step of performing the first etching process comprises etching the masking layer by anisotropic dry plasma etching.

5. The method of claim 1, wherein the step of performing the second etching process comprises etching away silicon dioxide in the MEMS structure by hydrofluoric acid vapor-phase etching (HF VPE).

6. The method of claim 1, further comprising the step of performing a third etching process by isotropic dry plasma etching to remove the masking layer in whole and a portion of the substrate beneath the MEMS structure.

7. The method of claim 1, wherein the blocking structure is made of metal and configured to stop an etching reaction medium from etching into the transistor structure from the MEMS structure.
